(19) United States
(12) Patent Application Publication
(10) Pub. No.: US 2013/0292247 A1
(43) Pub. Date: Nov. 7, 2013

(54) METHOD AND MICROSYSTEM FOR THE DETERMINATION OF CLAUSIUS-MOSSOTTI FACTORS FOR COLLOIDAL PARTICLES

(71) Applicants: David PEYRADE, Moirans (FR); Thibault Honegger, Grenoble (FR)

(72) Inventors: David PEYRADE, Moirans (FR); Thibault Honegger, Grenoble (FR)

(73) Assignee: COMMISSARIAT A L'ENERGIE ATOMIQUE ET AUX ENE ALT, Paris (FR)

(21) Appl. No.: 13/461,259

(22) Filed: May 1, 2012

(51) Int. Cl. G01N 27/447; B81B 7/02

(52) U.S. Cl. 204/518; 204/547; 204/643

(57) ABSTRACT

The invention concerns a method for determining Clausius-Mossotti Factors ‘CMF’ of a solution of colloidal particles, comprising the following steps:
putting said solution of colloidal particles (1) in contact with at least a pair of coplanar electrodes (3a, 3b) arranged on a substrate (5);
placing colloidal particles in specific locations with reference to said electrodes;
applying an AC electric field with an adapted dielectrophoretic ‘DEP’ frequency between each pair of electrodes, so that the colloidal particles move away from said specific locations by DEP forces, the motion of the colloidal particles being dictated by a DEP regime;
determining velocities of the moving colloidal particles during the DEP regime, said velocities being determined along the electric field gradient direction; and
calculating the CMF of said colloidal particles by using said velocities.

### TECHNICAL FIELD

The present invention concerns the determination of electro kinetic properties of colloidal solutions, and more particularly the determination of Clausius-Mossotti factors of a solution of colloidal particles.

### PRIOR ART

Colloidal particles exhibit dielectrophoretic activity in the presence of electric fields. Consequently, dielectrophoresis has been used to manipulate, transport, and separate different types of colloidal particles in many scientific, industrial and medical applications. Indeed, the capability of a dielectrophoretic (DEP) force to either attract or repel polarisable colloidal particles in a polarisable medium makes it unique among contactless actuation forces. The nature of this force comes from the differences in polarisability between the colloidal particle and the medium in a non-uniform electric field. In fact, the strength of the DEP force depends on the medium and on the particles' electrical properties, shape and size, as well as on the frequency of the electrical field when this field is oscillating. In particular, depending on the frequency of the electrical field, the DEP force may be attractive or repulsive. The frequency, at which the DEP force is transformed from attractive to repulsive or vice versa, is called a crossover frequency. Consequently, in order to correctly apply DEP forces for manipulating different types of particles, it is important to determine their crossover frequencies. The crossover frequencies can also provide characterisation of the electrical properties of those particles.

Several methods to determine the crossover frequencies have been proposed. One example is illustrated by Green et al. in the publication entitled “Dielectrophoresis of Submicrometer Latex Spheres (Experimental Results)” J. Phs. Chem. B, vol. 103, pages 41-50, 1999. Green's method consists of visually estimating crossover frequencies of colloidal particles of different sizes. A crossover frequency is the frequency at which the particles are supposed to be stationary. However, colloidal particles are subject to a natural Brownian motion and thus, it is very difficult to achieve precise measurements of crossover frequencies. In addition, these frequencies are dependent on the physical and chemical properties of the particles as well as on their size.

Another method is illustrated by Wei et al., in “Direct measurements of the frequency-dependent dielectrophoresis force” Biomicrofluidics, vol. 3, 2009. This method is based on a coupled optical and DEP trapping technique in which micrometer sized particles could be trapped. Measuring the rotational speed of a trapped particle enables to precisely estimate the crossover frequencies. This method was able to measure very accurately the crossover frequency of 10 μm Au-grafted polystyrene particles in deionised (DI) water. However, this method is only applicable for micrometric size particles. Indeed, it is very difficult to measure the rotational speeds of particles whose diameters are less than 1

In view of the above, it is clear that the prior art methods are either too imprecise or only applicable for micrometric particles.

Moreover, the determination of crossover frequencies is not sufficient to precisely characterise the effects of DEP forces on colloidal particles especially at the microscales and the nanoscales.

The problem to be solved by the present invention is therefore to propose a simple, precise and reliable method for accurately characterising DEP forces acting on colloidal particles over a wide range of sizes.

### SUMMARY OF THE INVENTION

The object of the invention is to present a method for determining Clausius-Mossotti Factors (CMF) of a solution of colloidal particles, comprising the following steps:
putting said solution of colloidal particles in contact with at least a pair of coplanar electrodes arranged on a substrate;
placing colloidal particles in specific locations with reference to said electrodes;
applying an AC electric field with an adapted dielectrophoretic (DEP) frequency between each pair of electrodes, so that the colloidal particles move away from said specific locations by DEP forces, the motion of the colloidal particles being dictated by a DEP regime;
determining velocities of the moving colloidal particles during the DEP regime, said velocities being determined along the electric field gradient direction; and
calculating the CMF of said colloidal particles by using said velocities.

The Clausius-Mossotti factor (CMF) translates the difference in polarisation between a colloidal particle and the medium in which it is suspended and thus enables to accurately define the strength and the direction of the DEP force imposed on that particle.

The term “colloidal solution” should be understood here as a dispersed phase particles (or colloidal particles) dispersed throughout a liquid dispersion medium. In all the description, the dispersed phase as well as the dispersion medium is considered to be polarisable. The colloidal particles may be isotropic or anisotropic objects having a size of between approximately 5 nm and 100 nm. Such objects at the nanoscale may be metallic colloids (e.g., Au, Ag), non metallic colloids (e.g., nanotubes, PS), non biological colloids (e.g., semi-conductor colloids, dendrimers), or organic/biological colloids (e.g., proteins, DNA, virus). At the mesoscopic scale, the colloidal particles may be non biological colloids (e.g., latex, silica), or biological colloids (e.g., vesicles, bacteria, red blood cells, white blood cells, etc.).

The present invention presents thus a simple and repeatable method for directly and accurately determining the CMF of colloidal particles over a wide range of diameters based on the exploitation of advantageous hydrodynamical forces.

Advantageously, the colloidal particles are placed in said specific locations by electro-osmotic (ACEO) forces, under the effect of an AC electric field with an adapted ACEO frequency applied between said pair of electrodes.

Thus, the colloidal particles can be easily placed in said specific locations in a repeatable manner by simply changing the frequency of the applied electrical field.

Advantageously, said adapted dielectrophoretic (DEP) frequency is a positive dielectrophoretic (pDEP) frequency establishing a pDEP regime during which the colloidal particles move towards the electrodes' edges by pDEP forces.

Thus, the method takes advantage of the formation of a pure pDEP regime dictating the motion of colloidal particles for accurately extracting the CMF.

Advantageously, the frequency of the electric field is modified from said pDEP frequency into a negative dielectrophoretic (nDEP) frequency establishing an nDEP regime during which the colloidal particles move away from the electrodes' edges under the effect of an nDEP regime.

Thus, the method takes also advantage of the formation of a pure nDEP regime after the formation of the pDEP regime for accurately extracting the CMF over a whole range of frequencies.

Advantageously, the sequence of accessing the DEP regime after placing the colloidal particles in said specific locations is repeated by applying a different DEP frequency selected out of a determined range of DEP frequencies.

This enables to use the method over a wider range of particle diameters and to increase the accuracy of the CMF.

The determination of said velocities of the moving colloidal particles can comprises the following steps:
recording a video file of the colloidal particles' motion during the corresponding DEP regime, and
analysing said video file by tracking the particles in order to extract their velocities.

This enables to detect the positions of particles and calculate their trajectories and velocities in a simple, precise, and robust manner. The determination of velocities can also be done by laser means or electrical means or any other means that enables to measure the particles' velocities relatively to the electrodes.

Advantageously, the method comprises the step of using the CMF in order to determine the surface capacitance of colloidal particles.

According to an advantageous aspect of the present invention, said colloidal particles have diameters within the range of 5 nm to 100 m.

The present invention also presents a method for determining Clausius-Mossotti Factors (CMF) of a solution of colloidal particles, comprising the following steps:
putting said solution of colloidal particles in contact with at least a pair of coplanar electrodes arranged on a substrate;
placing colloidal particles in specific locations with reference to said electrodes, advantageously by electro-osmotic (ACEO) forces, under the effect of an AC electric field with an adapted ACEO frequency applied between said pair of electrodes;
modifying the frequency of the electric field from said ACEO frequency into a positive dielectrophoretic (pDEP) frequency establishing a pDEP regime during which the colloidal particles move away from said specific locations towards the electrodes' edges by pDEP forces, the motion of the colloidal particles being dictated by a pDEP regime;
reiterating the sequence of accessing the pDEP regime after placing the colloidal particles in said specific locations by spanning the applied pDEP frequency through a determined range of selected pDEP frequencies;
determining velocities of the moving colloidal particles during each sequence of a pDEP regime at the selected pDEP frequency, said velocities being determined along the electric field gradient direction; and
calculating the CMF of said colloidal particles for each selected pDEP frequency by using the corresponding velocities determined during each selected pDEP frequency.

The method further comprises the following steps:
modifying the frequency of the electric field after the establishment of a pDEP regime into a negative dielectrophoretic (nDEP) frequency establishing an nDEP regime during which the colloidal particles move away from the electrodes' edges under the effect of an nDEP regime,
reiterating the sequence of accessing the nDEP regime after the establishment of a pDEP regime by spanning the applied nDEP frequency through a determined range of selected nDEP frequencies;
determining velocities of the moving colloidal particles during each sequence of nDEP regime at the selected nDEP frequency, said velocities being determined along the electric field gradient direction; and
calculating the CMF of said colloidal particles for each selected nDEP frequency by using the corresponding velocities determined during each selected nDEP frequency.

The invention concerns also a microfluidic device, to implement the determination method according to the above features, said device comprising:
a lower substrate and an upper substrate arranged facing each other,
at least a pair of coplanar electrodes arranged on an upper surface of said lower substrate,
means for injecting a solution of colloidal particles so as to put said solution in contact with said electrodes,
electric means for applying an AC potential between each pair of electrodes, and
recording means for recording the movement of the colloidal particles under the effect of a DEP regime.

### BRIEF DESCRIPTION OF THE DRAWINGS

Embodiments of the invention will now be described, as non-limiting examples, referring to the attached drawings, in which:

FIGS. 1A and 1B show diagrammatically a method for determining the CMF of a solution of colloidal particles, according to the invention;

FIG. 2 shows diagrammatically a microfluidic device for determining the CMF of a solution of colloidal particles, according to the invention;

FIGS. 3A-3G show diagrammatically a method for determining the CMF of a solution of colloidal particles, according to a preferred embodiment of the invention;

FIGS. 4A-4D illustrate experimental plots of the real part of the CMF for a wide range of colloidal solutions comprising polystyrene (FIG. 4A), silica (FIG. 4B), gold (FIG. 4C), and lymphocytes (FIG. 4C), particles, according to the invention;

FIG. 5 illustrates experimental plots of the real part of the CMF for a wide range of functionalised colloidal silica particles, according to the invention.

FIG. 6A illustrates a plot of the surface capacitance of polystyrene, silica, and gold colloidal particles of different diameters, according to the invention; and

FIG. 6B illustrates a core-shell model describing a functionalized particle, according to the invention.

### DETAILED PRESENTATION OF A PREFERRED EMBODIMENT

The present invention proposes a method to determine the Clausius-Mossotti factors (CMF) and surface capacitances of colloidal particles in order to make the most of dielectrophoresis (DEP) for a high-precision manipulation of different types of particles in many industrial and medical fields. It is based on the exploitation of AC electrokinetics phenomena to preconcentrate colloidal particles before establishing a pure DEP regime during which a particle displacement is observed in order to measure its velocity which is directly correlated to the CMF.

The dielectrophoretic force [symbol] F_{DEP} [symbol] generated by a non uniform oscillating (e.g. AC) electric field E on a particle of radius a in a medium of permittivity εₘ is given by the following equation:

[symbol]

F_{DEP} [symbol] =2πεₘa^{a}Re—(K(ω))V|E|² (1)

where Re(K(ω)) is the real part of the CMF K(ω) which translates the difference in polarization between the particle itself and the medium in which it is suspended. The CMF K(ω) depends on the complex permittivity of the medium ε̅ₘ, the complex permittivity of the particle ε̅ₚ (via the conductivity σ_{bulk} of the bulk particle material and the surface capacitance Kₛ of the colloid), and the angular frequency ω of the applied AC signal according to the following equation:

$$\begin{matrix}K ( ω ) = \frac{{ɛ}_{p} - {ɛ}_{m}}{{ɛ}_{p} + {ɛ}_{m}} & ( 2 ) \\ where & \\ {\tilde{ɛ}}_{m} / p = {ɛ}_{m} / p - i \frac{{σ}_{m} / p}{ω} & \\ and & \\ {σ}_{p} = {σ}_{bulk} + 2 \frac{{K}_{s}}{a} & \end{matrix}$$

[symbol]

When a particle is suspended in a fluid, it is subjected to several forces. Gravity and buoyancy keep the particle in a static state. For objects bigger than 5 nm at low applied voltages, DEP can dominate electrokinetic hydrodynamical forces such as AC electro-osmosis (ACEO) and electrothermal effect (ETE).

On the other hand, the drag force F_{drag} for a colloidal particle of radius a placed into a fluid whose viscosity is η, is given by the following equation:

F_{drag}=6πaηUₚ (3a)

When applying an AC potential that induces DEP, the particle motion equilibrates the motion of the surrounding liquid, resulting in the equality between the dielectrophoretic and drag forces:

[symbol]

F_{DEP} [symbol] =F_{drag} (3b)

Until the particle is out of the DEP range (where V|E|² falls), the motion of the particle is dictated by a pure DEP regime. Thus, during this transition time, determining the velocity of the particle allows for direct correlation to the real part of the CMF (Re(CMF)) as given by the following equation:

$$Re ( K ( ω ) ) = α {U}_{p} \\ where \\ α = \frac{3 η}{{a}^{2} {ɛ}_{m} ∇ {\vert E \vert}^{2}} \qquad ( 4 )$$

[symbol]

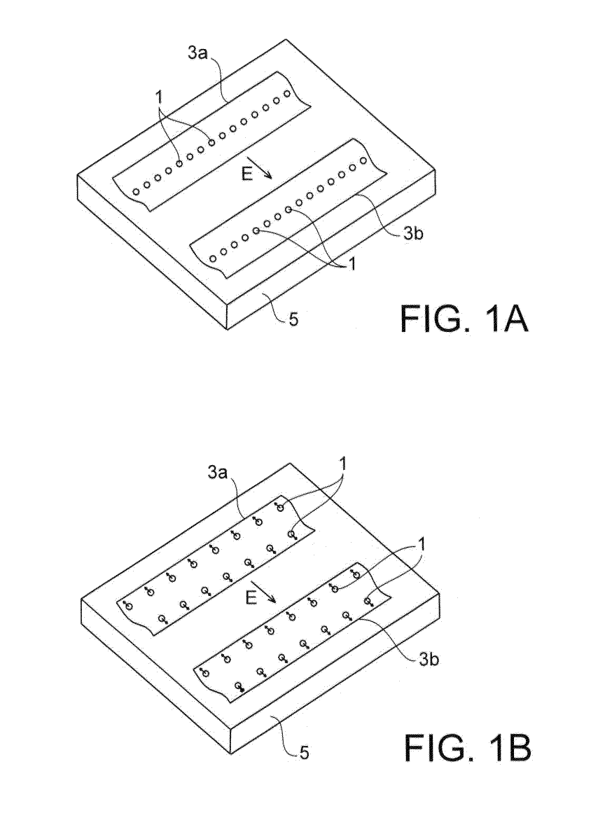

The determination of the CMF (more precisely Re(CMF), i.e., Re(K(ω))) according to the above concepts of the invention is described hereafter with reference to FIGS. 1A to 5.

FIGS. 1A and 1B show diagrammatically a method for determining the CMF of a solution of colloidal particles, according to the invention.

At first a solution of colloidal particles 1 are put in contact with at least a pair of coplanar electrodes 3a, 3b arranged on a substrate 5 of a microfluidic device.

In order to access the DEP regime, colloidal particles 1 are first placed in specific locations with reference to the electrodes. The particles may be positioned on top of the electrodes 3a, 3b or on sites outside the electrodes 3a, 3b by using any preconcentration means selected out of different types of means such as mechanical, optical, chemical, magnetic or electrical means.

Preferably, the colloidal particles 1 are placed in said specific locations by using electrical means. In particular, the colloidal particles 1 are placed in said specific locations by electro-osmotic (ACEO) forces, under the effect of an AC electric field E applied between each pair of electrodes 3a, 3b. The applied electric field E is chosen to have an adapted ACEO frequency (of the order of 1 kHz depending on the particle's size). This leads to the concentration of colloidal particles 1 for example along the centres of the electrodes 3a, 3b as depicted in FIG. 1A or in other specified locations depending among other things on the medium's conductivity.

Then an AC electric field with an adapted dielectrophoretic (DEP) frequency within the range of 10 kHz to 10 MHz (depending on the particle's size and nature) is applied between each pair of electrodes 3a, 3b, so that the colloidal particles 1 move away from the specific locations by DEP forces. The motion of the colloidal particles 1 during this phase is dictated by a DEP regime.

In particular, in case the colloidal particles 1 have been placed along the centres of the electrodes 3a, 3b by electro-osmotic (ACEO) forces, the frequency of the electric field is simply modified from an ACEO frequency into a DEP frequency so as to put particles in motion in the plane of the electrodes 3a, 3b away from their centres by dielectrophoretic forces (FIG. 1B).

It is to be noted that the DEP regime can be a positive DEP (pDEP) regime or a negative DEP (nDEP) regime. For example, if the particles 1 where originally preconcentrated along the centre of an electrode, the establishment of a pDEP regime induces an attraction of the particles 1 towards the electrode edges. In an nDEP regime, particles 1 are repelled away from the electrode 3a, 3b. The crossover frequency and the DEP frequency regimes (pDEP and nDEP) can be roughly estimated by spanning the applied frequency from for example 1 kHz to 10 MHz depending on the type of particles.

During a DEP regime, the velocities of the moving colloidal particles 1 in the electric field gradient direction are determined. These velocities are then used to calculate the CMF of the colloidal particles according to Eq. (4).

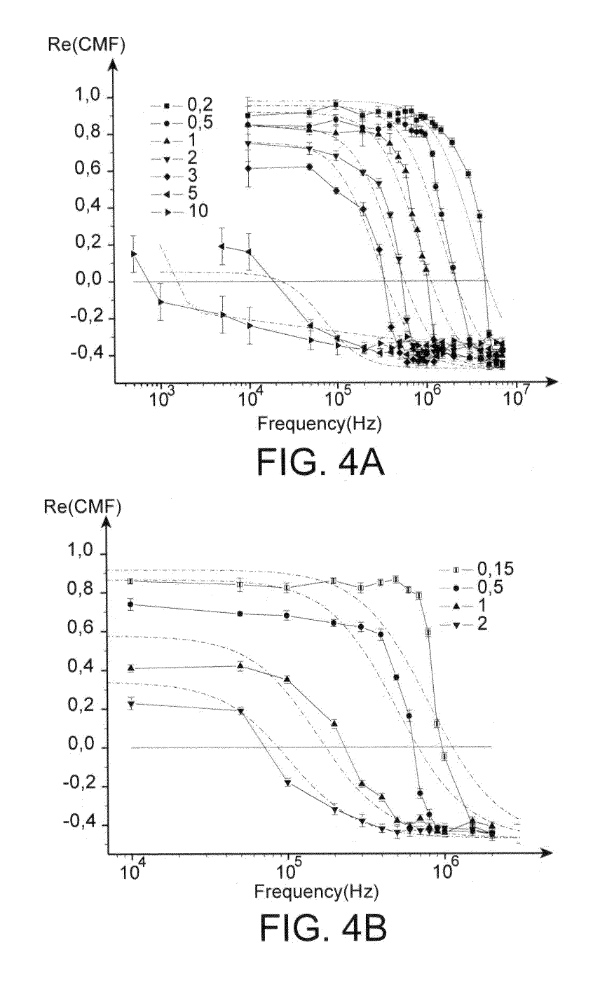

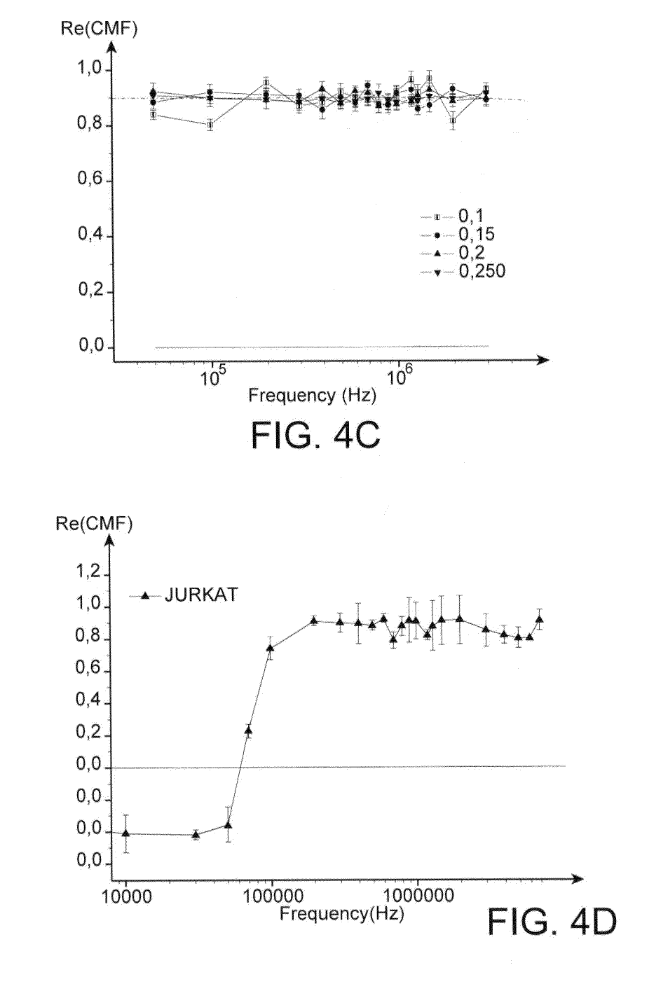

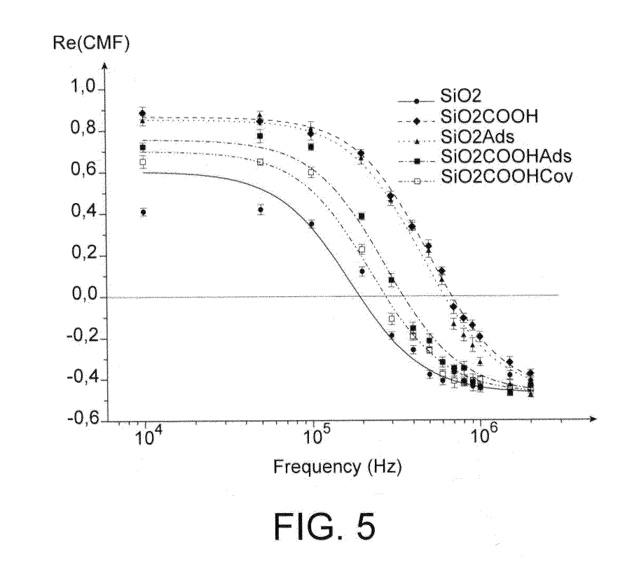

Advantageously, the sequence of accessing the DEP regime (pDEP or nDEP) after preconcentrating the particles is repeated by applying a different DEP frequency selected out of a determined range of DEP frequencies. This sequence may be repeated a predetermined number of times with a different DEP frequency at each time. In that case, average velocities of the moving colloidal particles 1 are determined for each selected DEP frequency and the CMF is then determined in function of each selected DEP frequency. This enables to plot the CMF over a wide range of selected DEP frequencies (see FIGS. 4A-5).

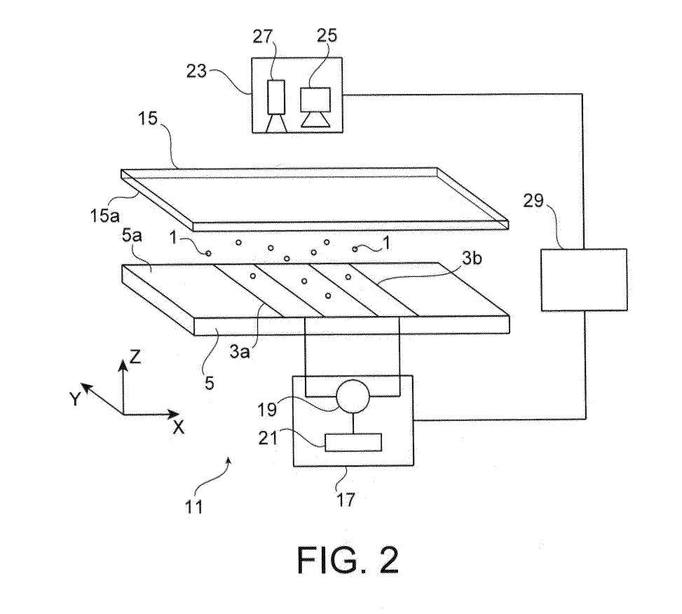

FIG. 2 shows diagrammatically a microfluidic device for determining the Clausius-Mossotti factors, according to the invention.

The microfluidic device 11 comprises a lower substrate 5 and an upper transparent substrate 15 forming a cover, arranged facing each other. Hereafter, the upper surface of the lower substrate is called the first surface 5a and the lower surface of the upper substrate is called the second surface 15a. The first and second surfaces 5a, 15a are opposite to each other and are separated by a distance which can be of the order of a few tens of microns, e.g. 50 μm.

The lower substrate 5 can be implemented in a material such as monocrystalline silicon, polycrystalline silicon, silicon nitride, silicon oxide, or polydimethylsiloxane PDMS. The material of the upper substrate 15 can be chosen from among the above-mentioned materials, but PDMS, glass, pyrex or an organic material such as polycarbonate or PEEK will be preferred. The thickness of each substrate 5, 15 can be between a few hundred microns and a few millimetres.

In all the description below, by convention a direct orthonormal frame in Cartesian co-ordinates (X, Y, Z) is used, as shown in FIG. 2. The plane (X, Y) is parallel to the first 5a and second 15a surfaces, and the direction Z is oriented from the first surface 5a to the second surface 15a.

The terms “upper” and “lower” should be understood here in terms of orientation following the direction Z of said frame.

At least one pair of coplanar electrodes 3a, 3b is arranged on the first surface 5a. The electrodes 3a, 3b are each formed of a track implemented in a metallic material, e.g. gold or aluminium. They are parallel to each other, coplanar and approximately rectilinear. Only one pair of electrodes 3a, 3b is shown in FIG. 2.

The electrodes 3a, 3b are connected to electric means 17 (comprising a voltage generator 19 and control means 21), which makes it possible to apply a potential difference between the electrodes 3a, 3b.

The voltage which is applied is an alternating voltage of the order of a few RMS volts, the frequency of which is, for example, between 1 kHz and 10 MHz.

The control means 21 are connected to the voltage generator 19, for choosing the parameters of the frequency and voltage to be set.

The electrodes 3a, 3b are separated from each other by a distance several times greater than the diameter of the targeted particle. Preferably the space between the electrodes 3a, 3b is chosen to be ten times greater than the diameter of the particle in order to create a quasi-constant electric field between them. The width of each electrode 3a, 3b is also chosen to be several times greater than the diameter of the targeted particle and can be of the order of 10 μm to 50 μm.

Recording means 23 (comprising a camera 25 and illuminating means 27) is installed above the upper substrate 15, for recording the movement of the colloidal particles 1. Alternatively, the camera 25 and/or the illuminating means 27 can be installed under the lower substrate 5 in case the latter is implemented in a transparent material.

Advantageously, the camera 25, the illuminating means 27, and the control means 17 are connected to processing means 29 (for example, a computer system) comprising a computer program containing code instructions adapted to implement the determination method according to the invention.

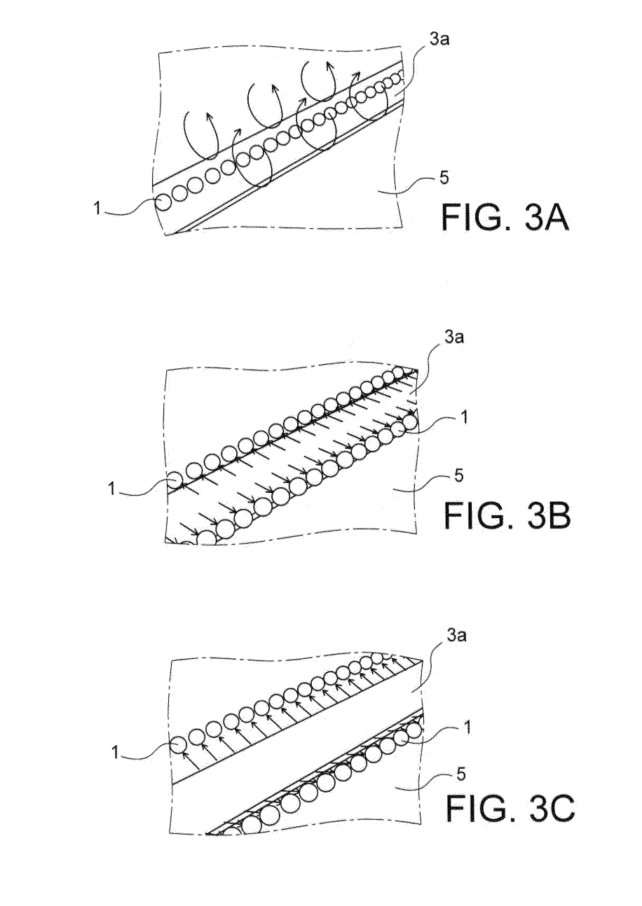

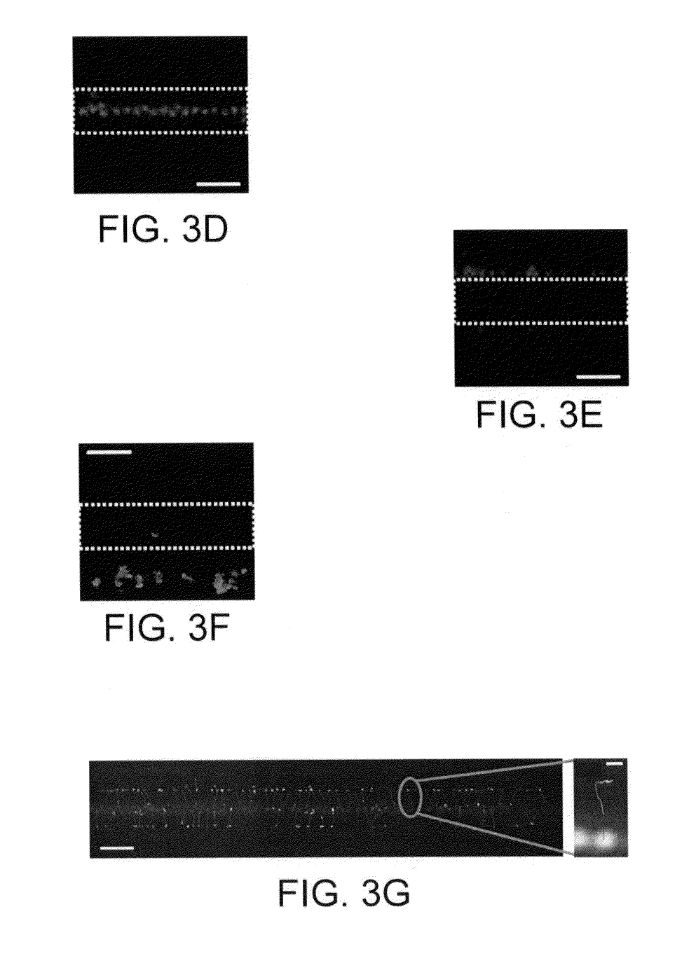

The microfluidic device 11 according to the preferred embodiment of the invention operates as follows, referring to FIGS. 3A to 3G.

According to a first step, injection means (for example a syringe) is used to inject a solution of colloidal particles 1 through an opening of the microfluidic device 11 so as to put the solution in contact with the pair or pairs of electrodes 3a, 3b arranged on the first surface 13a of the lower substrate 5. The colloidal particles 1 can be any sort of particles such as polystyrene (PS), silica (SiO₃), metallic particles (e.g. Au, Ag), or biological particles (e.g. proteins, DNA, virus, vesicles, bacteria, blood particles) from 1 nm to 100 μm.

After stopping the injection of the colloidal solution, an AC potential (generating a non-uniform electric field E) is applied between each pair of electrodes 3a, 3b with an adapted ACEO frequency.

FIG. 3A shows the concentration of particles 1 aligned in a specific location above the centre of one electrode 3a. For example under the effect of an electric field with an AC frequency of 1 kHz in a low conductivity media such as de-ionized (DI) water, the fluid motion drags particles 1 towards the centre of each electrode 3a, 3b. The curled arrows represent the ACEO-induced convectional motion of the solution. Advantageously, voltages Vₚ₋ₚ are not to exceed 3 V to limit the ETE effect.

In order to quantify pDEP-induced motion, the frequency of the electric field is modified from the ACEO frequency into a pDEP frequency (e.g., typically 100 kHz for 1 μm PS particles). Thus, a pDEP regime is established during which the colloidal particles 1 move away from the centres towards the electrodes' edges by pDEP forces represented by straight arrows. During the transition time of the pDEP regime (i.e. during the particles shift from the electrode's centre towards its edges), particles' motion is recorded via the camera 25. This sequence is reproduced through the whole frequency range of the pDEP regime. For example, for polystyrene particles, pDEP frequencies are applied from 1 kHz to 1 MHz at intervening intervals of 50 kHz.

Advantageously, the AC frequency sequence and particles motion grab are automatically triggered by the processing means 29. Illumination during the recording can be either dark field or fluorescence depending on the type of analysed particles. It is to be noted that submicrometer particles having diameters less than 200 nm, are fluorescently marked and are visualised via a camera comprising a microscope objective. Recording images are then compiled into a film according to the camera frame rate (typically 20 fps).

Advantageously, for nDEP-induced motion, a three-step protocol is applied. First, particles 1 are concentrated in the centre of each electrode 3a, 3b by ACEO (e.g., typically at 1 kHz for PS particles), and then towards the edges of the corresponding electrode by pDEP (e.g., typically at 100 kHz for PS particles). The selected nDEP frequency is then applied and particle motion is recorded until the particles are far away from the corresponding electrode edge as shown in FIG. 3C (typically when Brownian motion dominates the motion of the particle, i.e., when V_{y}>0). This sequence is reproduced through the whole frequency range of the nDEP regime. For example, for polystyrene particles, nDEP frequencies from 1.5 MHz to 10 MHz are applied at intervening intervals of 500 kHz.

Advantageously, the processing means 29 commands the control means for automatically applying a spanning frequency within the range of 1 kHz to 10 MHz in order to generate a succession of complete sequences of ACEO-pDEP-nDEP regimes while simultaneously commanding the recording means 17 to continuously record these sequences.

At each sequence, an initial ACEO frequency is applied to concentrate the particles 1, and then the frequency is modified into a pDEP frequency establishing a pDEP regime. Then, the frequency of the electric field is modified from the pDEP frequency into an nDEP frequency establishing an nDEP regime during which the colloidal particles 1 move away from the electrodes' edges under the effect of a pure nDEP regime. The sequence is repeated such that at each current sequence the applied pDEP and nDEP frequencies are equal to those applied at the preceding sequence augmented by predetermined pDEP and nDEP frequency intervals. For example, for PS particles, the applied pDEP frequency is initially started at 1 kHz and is increased at each consecutive sequence by a pDEP frequency interval of 50 kHz, whereas, the applied nDEP frequency may be initially started at 1.5 MHz and may be increased at each consecutive sequence by an nDEP frequency interval of 500 kHz.

FIGS. 3D-3F show a sequence of optical microscope images of 1 μm PS fluorescent particles subjected to different AC potentials. According to this example, particles are first positioned in the centre of the electrode by ACEO at 1 kHz and Vₚ₋ₚ=2V (FIG. 3D). Then particles are positioned at the edge of the electrode by pDEP at 100 kHz and Vₚ₋ₚ=2V (FIG. 3E). Finally particles are repelled from the electrode edges by nDEP at 1.5 MHz and Vₚ₋ₚ=2V (FIG. 3E). The scale bar is 10 μm.

The video file of the colloidal particles' motion recorded by the camera 25 during each corresponding DEP regime is sent to the processing means 29 for analysis. The processing means 29 uses an image processing program (for example, an IMAGEJ software) for tracking the particles 1 in order to determine their velocities. An analysis of particle motion is described for example in the publication of Sbalzarini et al., J. Struct. Biol. 151, 182 (2005). The image processing program is capable of tracking multiple particles in the same video file and outputting their velocities. An example of the particle tracking output with IMAGEJ is shown in FIG. 3G. In particular, it shows a particle tracking velocimetry plot of 1 μm PS particles from recorded video above the electrodes. The inset shows the trajectory of a single particle (scale bar is 1 μm).

It is to be noted that submicrometer particles (i.e. less than 400 nm in diameter) may not be individually distinguished and thus in that case, analysis is advantageously performed by averaging the position of groups of such particles.

For each selected frequency, extracted velocities in the electric field gradient direction are statistically analysed by the processing means 29 for a predetermined number of particles (for example greater than 50 particles). At each selected frequency, the processing means 29 determines the average velocity of the moving colloidal particles 1 during the pDEP or nDEP regime.

The processing means 19 is also configured to determine the Re(K(w)) in function of each selected frequency by dividing the particles' corresponding average velocity in the electric field gradient direction (X-axis according to FIG. 2) by the a factor according to Eq. 4.

The α factor is defined in terms of the gradient of the norm of the applied electric field (i.e. the value of V|E|² given in the expression of α). The value of V|E|² is extracted by using a simulation software (for example COMSOL 4.0 simulations). In such simulations, the potential applied to the electrodes 3a, 3b is multiplied by a correction factor that takes into account a potential drop across the coplanar electrodes 3a, 3b as calculated for example in the publication of Gonzalez et al. Phys. Rev. E 61, 4019 (2000). This drop is frequency dependent and alters the electric field computation only when the frequency is less than 5 Hz in low conductivity media. It is to be noted that the value of V|E|² (and hence the computation of the α factor) is not altered by particle-particle interactions. Indeed, according to the method of the present invention, the electric field and electric field gradient directions are in the same plane (X-Z plane on FIG. 2) and particles are aligned in a close-packed configuration along the perpendicular direction (Y-axis) of the gradient lines.

FIGS. 4A-4D illustrate experimental plots of the real part of the CMF (i.e. Re(K(ω))) for a wide range of colloidal solutions comprising polystyrene (FIG. 4A), silica (FIG. 4B), gold (FIG. 4C) and biological (FIG. 4D) particles.

In order to obtain these plots, each pDEP regime is established after an ACEO regime whereas, each nDEP regime is established after a pDEP regime. In particular, the sequence of accessing the pDEP regime after placing the colloidal particles in specific locations is reiterated by spanning the applied pDEP frequency through a determined range of selected pDEP frequencies. On the other hand, the sequence of accessing the nDEP regime after the establishment of a pDEP regime is reiterated by spanning the applied nDEP frequency through a determined range of selected nDEP frequencies.

In particular, FIG. 4A illustrates the plot of the Re(K(w)) for polystyrene ‘PS’ particles from 0.2 μm to 10 μm in diameter; FIG. 4B illustrates the plot of the Re(CMF) for silica ‘SiO₂’ particles from 0.15 μm to 2 μm in diameter; FIG. 4C illustrates the plot of the Re(CMF) for gold ‘Au’ particles from 0.1 μm to 0.25 μm in diameter; and finally FIG. 4D illustrates the plot of the Re(CMF) for biological cells.

All solutions are diluted in low conductivity media (i.e., having a conductivity cm less than

$$2 \times \frac{{10}^{- 2} S}{m} )$$

to a 1 wt. % particle concentration. In particular, non biological solutions (FIGS. 4A-4C) are diluted in DI water (having for example a conductivity of

$${σ}_{m} = 2 \times \frac{{10}^{- 4} S}{m}$$

and a permittivity of εₘ=78.5).

For PS and silica particles, the drop in the cross-over frequency and the Re(K(w)) maxima can be clearly seen through the different diameters (FIGS. 4A, 4B). PS and silica particles clearly demonstrate pDEP and nDEP behaviors at low and high frequencies respectively. However, it is well known that metallic particles, especially Au particles, have a constant positive response to DEP since these particles are always more polarisable than the DI water medium at frequencies below 10 MHz. FIG. 4C clearly shows the constant behavior of the Au particles.

FIG. 4D illustrates the experimental plot of the Re(CMF) for lymphoma cells derived from lymphocytes T (Jurkat cell line).

The lymphoma cells are diluted in a sucrose-dextrose solution (having a conductivity of

$${σ}_{m} = 2 \times \frac{{10}^{- 4} S}{m} ) .$$

Contrary to the behavior of non biological particles (FIGS. 4A-4c) lymphoma cells demonstrate an nDEP behavior at low frequencies and a pDEP behavior at high frequencies as depicted in FIG. 4D.

Advantageously, the colloidal particles can be special types of particles such as functionalised colloidal particles or Janus colloidal particles. Functionalised particles are colloidal particles grafted with proteins or other complex molecules, by adsorption or covalent links. Janus particles are particles whose surface has two or more different properties allowing different physical, chemical or biological effects to occur on the same particle.

FIG. 5 is an example illustrating plots of Re(K(w)) for a wide range of functionalized colloidal silica particles.

In particular, it illustrates the plots of the CMF for simple SiO₂ particles, simple SiO₂—COOH particles; silica particles grafted with proteins by adsorption SiO₂Ads; SiO₂—COOH grafted with proteins by adsorption SiO₂—COOHAds; and SiO₂—COOH grafted with proteins by covalent links SiO₂—COOHCov. The SiO₂ and SiO₂—COON particles without protein have respectively the highest (667 kHz) and lowest (237 kHz) crossover frequencies. Particles grafted with proteins have diminishing crossover frequencies in the following order: SiO₂ (635 kHz), SiO₂—COOHAds (330 kHz), and SiO₂—COOHCov (262 kHz).

On the other hand, once the value of the real part of the CMF (i.e. Re(K(ω))) for a colloidal particle is determined, it is then possible to extract its surface capacitance Kₛ value.

For example for a simple colloidal particle the surface capacitance Kₛ extracted according to the following equation:

$$Re ( K ( ω ) ) = \frac{( {ɛ}_{p} - {ɛ}_{m} ) ( {ɛ}_{p} + 2 {ɛ}_{m} ) - \frac{( {σ}_{m} - {σ}_{p} ) ( {σ}_{m} + \frac{{K}_{s}}{a} )}{{( ω / 2 )}^{2}}}{{( {ɛ}_{p} + 2 {ɛ}_{m} )}^{2} + \frac{{( {σ}_{m} + \frac{{K}_{s}}{a} )}^{2}}{{( ω / 2 )}^{2}}} \qquad ( 5 )$$

This enables the determination of the CMF of such particles in any medium in which it is suspended provided the surface capacitance of the latter is known.

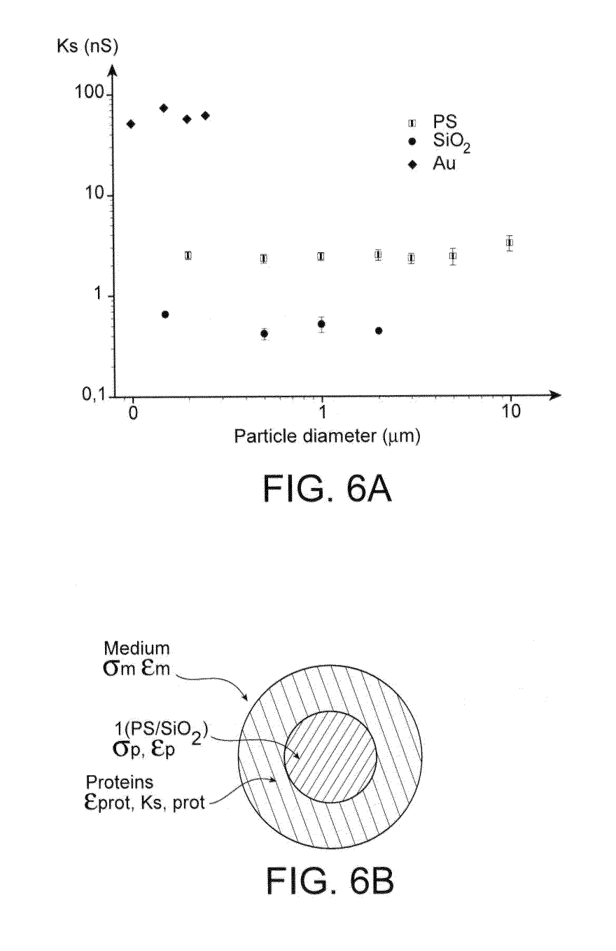

Indeed, FIG. 6A illustrates a plot of the surface capacitance of polystyrene, silica, and gold colloidal particles of different diameters. The plot shows a quasi constant surface capacitance Kₛ behavior for PS particles (ε_{PS}=2.55) except for the 10 μm particles.

However, for functionalized particles such as colloidal particles grafted with proteins, it is necessary to take into account the protein shell's screening effect that reduces the intensity of the electric field on the core of the particle.

Indeed, FIG. 6B illustrates a core-shell model describing a functionalized particle. In particular it shows a PS or silica particle 1 grafted with proteins in a low conductivity media. The core of radius a₁ represents the PS or silica particle 1 having a surface capacitance Kₛ which can be determined by Eq. (5). The shell of radius aₐ comprises n layers of protein coatings having a thickness of n·d_{proz} where dₚᵣₒₜ represents the hydrodynamic gyration radius of fibronectin (e.g., dₚᵣₒₜ=8 nm). The shell's surface capacitance K_{s.prot} is usually measured by other known methods (e.g., K_{s.prot}=4.4 nS) and the shell's permittivity is designated by εₚᵣₒₜ. The media is for example a DI water having a predetermined conductivity σₘ and a predetermined permittivity εₘ.

The CMF of the functionalized particle K(ω)ₚ₊ₚᵣₒₜ depends on the number n of protein layers as well as on the shell's permittivity εₚᵣₒₜ according to the following equations:

$$\begin{matrix} {K ( ω )}_{p + prot} = \frac{\text{?} - \text{?}}{\text{?} + \text{?}} & ( 6 ) \\ where & \\ \text{?} = \text{?} \frac{\text{?} + 2 K ( \text{?} )}{\text{?} - 2 K ( \text{?} )} ; & \\ \text{?} = {a}_{1} / \text{?} ; & \\ K ( \text{?} ) = \frac{{\tilde{ɛ}}_{p} - {\tilde{ɛ}}_{prot}}{\text{?} + 2 {\tilde{ɛ}}_{prot}} ; & \\ {\tilde{ɛ}}_{prot} = {ɛ}_{prot} + i \frac{2 {K}_{s . prot}}{ω \text{?}} & \\ and & \\ \text{?} = \text{?} + n . {d}_{prot} & \\ \text{?} \text{indicates text missing or illegible when filed} & \end{matrix}$$

With reference to the experimental plots of Re(K(w)) for a functionalized particle over the whole range of frequencies (FIG. 5) as well as to the above equations (6), the number n of protein layers and the shell's permittivity εₚᵣₒₜ can be easily determined. For example, it has been found out (according to the plots of FIG. 5 and Eq. (6)) that for silica particles grafted with proteins by adsorption SiO₂Ads and SiO₂—COOHAds, the corresponding numbers n of protein layers are 38 and 7, respectively and the corresponding permittivities εₚᵣₒₜ are around 2.01 and 1.97, respectively.

Thus, measuring intrinsic parameters (CMF and/or surface capacitance) of colloidal particles enables to detect or differentiate between these particles as well as to determine for example the number of protein layers on a functionalized particle. It also enables to use multifunctional particles suspended in different types of fluids for a wide range of dielectrophoretic applications including for example the separation of different types of particles.

1. Method for determining Clausius-Mossotti Factors (CMF) of a solution of colloidal particles, characterized in that it comprises the following steps:
putting said solution of colloidal particles in contact with at least a pair of coplanar electrodes arranged on a substrate;
placing colloidal particles in specific locations with reference to said electrodes;
applying an AC electric field with an adapted dielectrophoretic (DEP) frequency between each pair of electrodes, so that the colloidal particles move away from said specific locations by DEP forces, the motion of the colloidal particles being dictated by a DEP regime;
determining velocities of the moving colloidal particles during the DEP regime, said velocities being determined along the electric field gradient direction; and
calculating the CMF of said colloidal particles by using said velocities.

2. Method according to claim 1, wherein the colloidal particles are placed in said specific locations by electro-osmotic (ACEO) forces, under the effect of an AC electric field with an adapted ACEO frequency applied between said pair of electrodes.

3. Method according to claim 1, wherein said adapted dielectrophoretic (DEP) frequency is a positive dielectrophoretic (pDEP) frequency establishing a pDEP regime during which the colloidal particles move towards the electrodes' edges by pDEP forces.

4. Method according to claim 2, wherein the frequency of the electric field is modified from said pDEP frequency into a negative dielectrophoretic (nDEP) frequency establishing an nDEP regime during which the colloidal particles move away from the electrodes' edges under the effect of an nDEP regime.

5. Method according to claim 1, wherein the sequence of accessing the DEP regime after placing the colloidal particles in said specific locations is repeated by applying a different DEP frequency selected out of a determined range of DEP frequencies.

6. Method according to claim 1, wherein the determination of said velocities of the moving colloidal particles comprises the following steps:
recording a video file of the colloidal particles' motion during the corresponding DEP regime, and
analysing said video file by tracking the particles in order to extract their velocities.

7. Method according to claim 1, wherein it comprises the step of using the CMF in order to determine the surface capacitance of colloidal particles.

8. Method according to claim 1, wherein said colloidal particles have diameters within the range of nm to 100 μm.

9. Method for determining Clausius-Mossotti Factors (CMF) of a solution of colloidal particles, characterized in that it comprises the following steps:
putting said solution of colloidal particles in contact with at least a pair of coplanar electrodes arranged on a substrate;
placing colloidal particles in specific locations with reference to said electrodes by electro-osmotic (ACED) forces, under the effect of an AC electric field with an adapted ACEO frequency applied between said pair of electrodes;
modifying the frequency of the electric field from said ACED frequency into a positive dielectrophoretic (pDEP) frequency establishing a pDEP regime during which the colloidal particles move away from said specific locations towards the electrodes' edges by pDEP forces, the motion of the colloidal particles being dictated by a pDEP regime;
reiterating the sequence of accessing the pDEP regime after placing the colloidal particles in said specific locations by spanning the applied pDEP frequency through a determined range of selected pDEP frequencies;
determining velocities of the moving colloidal particles during each sequence of a pDEP regime at the selected pDEP frequency, said velocities being determined along the electric field gradient direction; and
calculating the CMF of said colloidal particles for each selected pDEP frequency by using the corresponding velocities determined during said selected pDEP frequency.

10. Method according to claim 9, wherein it further comprises the following steps:
modifying the frequency of the electric field after the establishment of a pDEP regime into a negative dielectrophoretic (nDEP) frequency establishing an nDEP regime during which the colloidal particles move away from the electrodes' edges under the effect of an nDEP regime,
reiterating the sequence of accessing the nDEP regime after the establishment of a pDEP regime by spanning the applied nDEP frequency through a determined range of selected nDEP frequencies;
determining velocities of the moving colloidal particles during each sequence of nDEP regime at the selected nDEP frequency, said velocities being determined along the electric field gradient direction; and
calculating the CMF of said colloidal particles for each selected nDEP frequency by using the corresponding velocities determined during said selected nDEP frequency.

11. Microfluidic device, to implement the determination method according to claim 1, characterised in that it comprises:
a lower substrate and an upper substrate arranged facing each other,
at least a pair of coplanar electrodes arranged on an upper surface of said lower substrate,
means for injecting a solution of colloidal particles so as to put said solution in contact with said electrodes,
electric means for applying an AC potential between each pair of electrodes, and
recording means for recording the movement of the colloidal particles under the effect of a DEP regime.
